(19) United States
(12) Patent Application Publication
(10) Pub. No.: US 2017/0092725 A1
(43) Pub. Date: Mar. 30, 2017

(54) ACTIVATED THIN SILICON LAYERS

(71) Applicant: International Business Machines Corporation, Armonk, NY (US)

(72) Inventors: Takashi Ando, Tuckahoe, NY (US); Martin M. Frank, Dobbs Ferry, NY (US); Vijay Narayanan, New York, NY (US); John Rozen, Hastings on Hudson, NY (US)

(21) Appl. No.: 14/868,413

(22) Filed: Sep. 29, 2015

(51) Int. Cl. H01L 29/40; H01L 29/51; H01L 21/02

(52) U.S. Cl. CPC H01L 29/401; H01L 21/02164; H01L 21/0217; H01L 21/0214; H01L 21/02238; H01L 21/02247; H01L 21/02249; H01L 29/513

(57) ABSTRACT

A method for forming a layer of material on a silicon layer comprises depositing a layer of silicon material having a hydrophobic H-terminated surface on a substrate, forming a hydrophilic seed layer on the surface of the silicon material, and depositing an oxide material layer on the hydrophilic seed layer.

### BACKGROUND

The present invention relates to semiconductor devices, and more specifically, to the deposition of materials on substrates.

Fabricating semiconductor devices often involves depositing layers of materials on a substrate. Some deposition processes include chemisorption such as, atomic layer deposition processes that may be used to deposit layers of dielectric materials. Often such processes incur an undesirable incubation delay.

### SUMMARY

According to an embodiment of the present invention, a method for forming a layer of material on a silicon layer comprises depositing a layer of silicon material having a hydrophobic H-terminated surface on a substrate, forming a hydrophilic seed layer on the surface of the silicon material, and depositing an oxide material layer on the hydrophilic seed layer.

According to another embodiment of the present invention, a method for forming a gate stack of a semiconductor device comprises depositing a layer of silicon material having a hydrophobic H-terminated surface on a substrate, forming a hydrophilic seed layer on the surface of the silicon material, depositing a dielectric material layer on the hydrophilic seed layer, depositing an electrode material layer on the dielectric material layer, and patterning and etching to remove portions of the dielectric material layer and the electrode material layer to define a gate stack.

According to yet another embodiment of the present invention, a semiconductor device comprises a substrate, a layer of silicon material on the substrate, a gate stack arranged on the substrate, the gate stack comprising a hydrophilic seed layer arranged on the layer of silicon material, an oxide material disposed on the hydrophilic seed layer, and a source region arranged on the substrate adjacent to the gate stack, and a drain region arranged on the substrate adjacent to the gate stack.

Additional features and advantages are realized through the techniques of the present invention. Other embodiments and aspects of the invention are described in detail herein and are considered a part of the claimed invention. For a better understanding of the invention with the advantages and the features, refer to the description and to the drawings.

### BRIEF DESCRIPTION OF THE DRAWINGS

The subject matter which is regarded as the invention is particularly pointed out and distinctly claimed in the claims at the conclusion of the specification. The forgoing and other features, and advantages of the invention are apparent from the following detailed description taken in conjunction with the accompanying drawings in which:

FIG. 1 illustrates a side view of a substrate and a silicon layer.

FIG. 2 illustrates the formation of a seed layer on the surface of the silicon layer.

FIG. 3 illustrates the deposition of a dielectric layer on the seed layer.

FIG. 4 illustrates the formation of an electrode layer on the dielectric layer.

FIG. 5 illustrates an exemplary embodiment of a field effect transistor device (FET) device.

FIG. 6 illustrates an alternate exemplary embodiment of a gate stack.

FIG. 7 illustrates an exemplary embodiment of a thin film transistor device.

FIG. 8 illustrates an exemplary embodiment of a FET device that includes a seed layer.

FIG. 9 illustrates an exemplary embodiment of a thin film solar cell device.

FIG. 10 illustrates an exemplary embodiment of a hetero junction solar cell.

FIG. 11 illustrates a graph showing the relative thicknesses of a layer of dielectric material deposited after a short queue time.

FIG. 12 illustrates a graph showing the relative thicknesses of a layer of dielectric material deposited after a short queue time.

FIG. 13 illustrates a graph showing measured contact angle of H₂O₂ in degrees as a function of air exposure time in hours.

### DETAILED DESCRIPTION

The deposition of oxide materials on some silicon surfaces such as Si—H terminated surfaces often incurs an undesirable incubation delay because the Si—H terminated surfaces are hydrophobic. Over time, moisture can convert an Si—H terminated surface into a more reactive hydrophilic surface. The variation in the hydrophobic properties of the Si—H terminated surfaces often due to variations in process queue times before subsequent film deposition may result in undesirable variations in the thickness and insulating properties of dielectric material layers deposited on the Si—H terminated surfaces.

The embodiments described below condition the Si—H terminated surface to form a seed layer on a thin layer of deposited silicon material. The seed layer is hydrophilic and provides a surface that allows uniform deposition of materials such as, for example, dielectric materials, using a deposition process such as atomic layer deposition (ALD), chemical vapor deposition (CVD) and epitaxial growth processes.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

As used herein, the articles “a” and “an” preceding an element or component are intended to be nonrestrictive regarding the number of instances (i.e. occurrences) of the element or component. Therefore, “a” or “an” should be read to include one or at least one, and the singular word form of the element or component also includes the plural unless the number is obviously meant to be singular.

As used herein, the terms “invention” or “present invention” are non-limiting terms and not intended to refer to any single aspect of the particular invention but encompass all possible aspects as described in the specification and the claims.

As used herein, the term “about” modifying the quantity of an ingredient, component, or reactant of the invention employed refers to variation in the numerical quantity that can occur, for example, through typical measuring and liquid handling procedures used for making concentrates or solutions. Furthermore, variation can occur from inadvertent error in measuring procedures, differences in the manufacture, source, or purity of the ingredients employed to make the compositions or carry out the methods, and the like. In one aspect, the term “about” means within 10% of the reported numerical value. In another aspect, the term “about” means within 5% of the reported numerical value. Yet, in another aspect, the term “about” means within 10, 9, 8, 7, 6, 5, 4, 3, 2, or 1% of the reported numerical value.

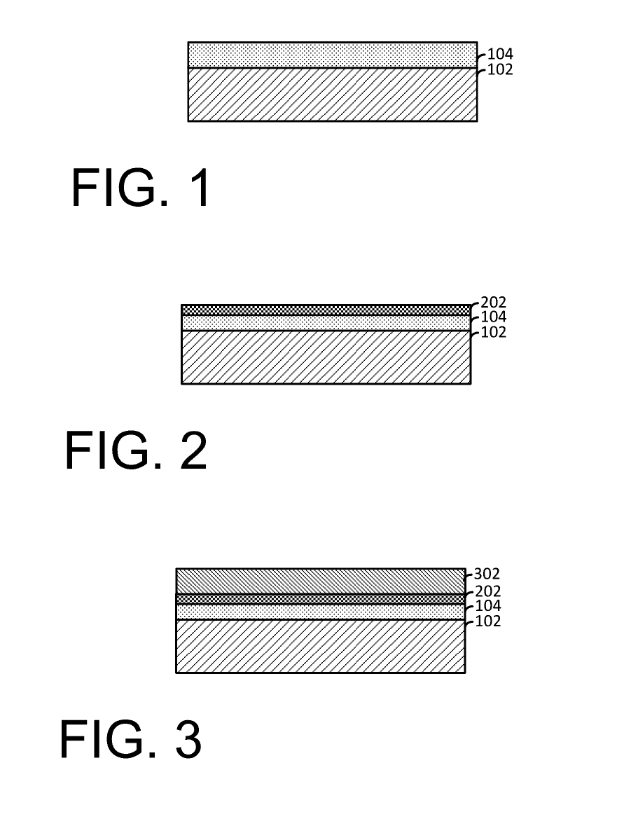

FIG. 1 illustrates a side view of a substrate 102. The substrate 102 may include, for example, a bulk silicon, a silicon germanium, germanium, a high mobility material such as, InGaAs, GaAs, InAs, InAlAs, a wide band gap material such as, SiC or GaN, or an insulator material such as an oxide material. In the illustrated embodiment, the substrate 102 includes a semiconductor material. A thin silicon layer 104 is formed on the substrate 102. The silicon layer 104 may include, for example, amorphous silicon (aSi), hydrogenated amorphous silicon (aSi:H), polysilicon, nanocrystalline silicon (nc-Si), or hydrogenated nanocrystalline silicon (nc-Si:H). The silicon layer 104 may be formed by, for example, chemical vapor deposition (CVD) process, a plasma-enhanced chemical vapor deposition (PECVD) process, remote plasma chemical vapor deposition (RPCVD), hot-wire chemical vapor deposition (HWCVD), atomic layer deposition (ALD), molecular beam epitaxy, e-beam deposition, or any SiₓH_{y} based process. The silicon layer 104 may have a range of thickness depending on the device being formed, for example, a dielectric layer in a logical FET may have a thickness up to about 20 angstroms, a thin film in solar cells has a thickness of about 100 angstroms to 1 micrometer, a thin film transistor may have a thickness of about 1 micrometer.

FIG. 2 illustrates the formation of a seed layer 202 on the surface of the silicon layer 104. The seed layer 202 may be formed by exposing the silicon layer 104 to oxidizing or nitriding gasses such as, for example, O₂, O₃, H₂O, NH₃, NO, N₂O, corresponding plasmas, and deuterated analogs. The seed layer 202 includes, for example, SiO, SiN, or SiON depending on the process used to form the seed layer. The seed layer 202 has a relatively thin thickness and may include, in some embodiments, a monolayer of about 3 angstroms. The seed layer 202 in one exemplary embodiment is formed by exposure to O₃ for about 2 seconds to 60 seconds at about 2 Torr at 300 degrees Celsius. Such a process provides a surface that is no longer dominantly Si—H terminated without changing the bulk properties of the underlying thin Si.

In an alternate exemplary embodiment, the seed layer 202 may be formed by immersing in, or exposing the silicon layer 104 to a vapor of, for example, H₂O₂, O₃/H₂O, NH₄OH, NH₄OH/H₂O₂, or HCl/H₂O₂. and their solutions in H₂O.

FIG. 3 illustrates the deposition of a dielectric layer 302 on the seed layer 202. The dielectric layer 302 may be formed by, for example, an ALD process. The dielectric layer 302 includes, for example, SiO, HfO, SiN, SiON, LaO, or AlO. The seed layer 202 provides a hydrophilic surface that allows the dielectric layer 302 to be deposited uniformly without an incubation delay prior to depositing the dielectric layer 302.

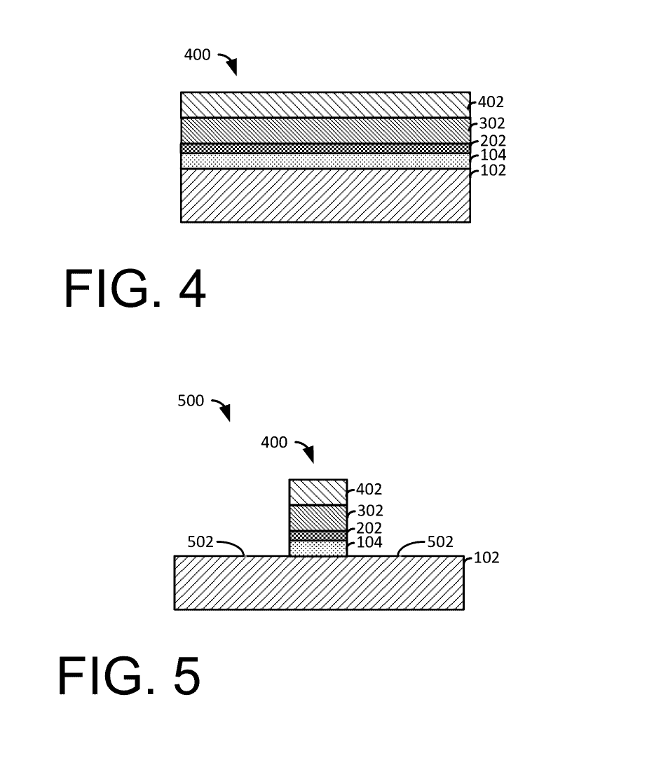

FIG. 4 illustrates the formation of an electrode layer 402 on the dielectric layer 302. The electrode layer 402 may include, for example, a TiN, polysilicon, Ti, Al, Au, or Pd material. Once the electrode layer 402 is formed, the dielectric layer 302 and the electrode layer 402 may be patterned to form a gate stack 400.

FIG. 5 illustrates an exemplary embodiment of a field effect transistor device (FET) device 500 that includes active (source/drain) regions 502 that are arranged on the substrate 102 adjacent to the gates stack 400. The gate stack 400 may be used in a variety of semiconductor devices such as, for example, planar or three-dimensional FETs, including FINs, nanowires, nanosheets, vertical FET. The gate stack 400 may be formed using a gate-first or gate-last scheme.

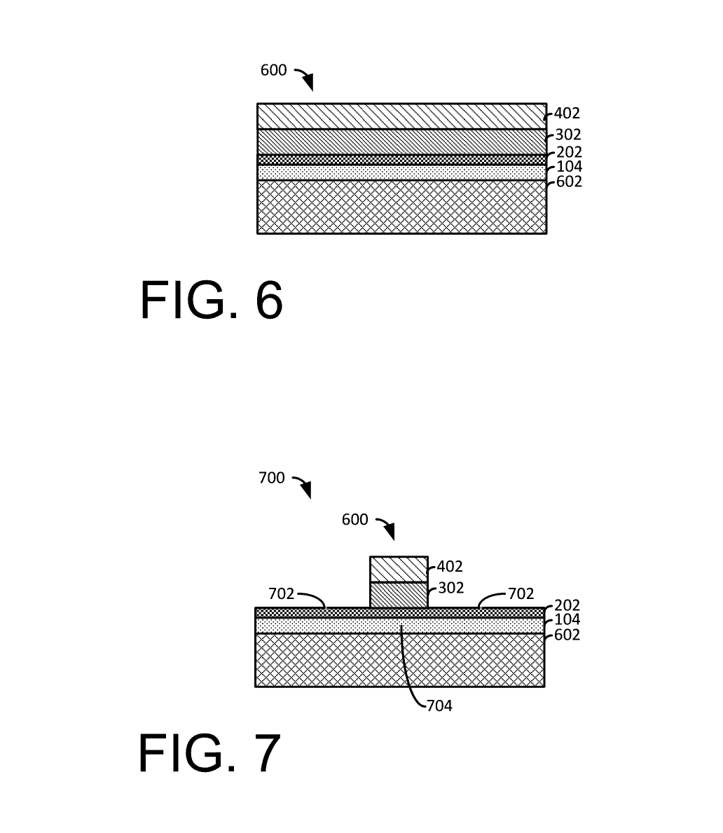

FIG. 6 illustrates an alternate exemplary embodiment of a gate stack 600 that has been formed on a substrate 602 that includes an insulator material, such as, for example, SiO₂. The gate stack 600 may be used in, for example a thin film transistor (TFT) device.

FIG. 7 illustrates an exemplary embodiment of a TFT device 700 in the form of a coplanar structure. The device 700 includes active regions 702 adjacent to the gate stack 600. The gate stack 600 is arranged over a channel region 704 of the silicon layer 104. The gate stack 600 can also be used in a staggered TFT structure.

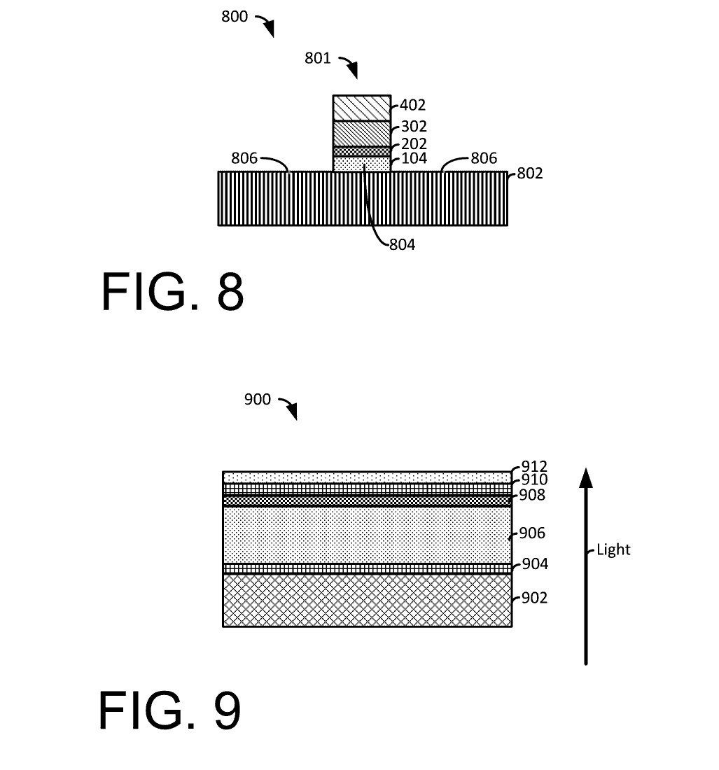

FIG. 8 illustrates an exemplary embodiment of a FET device 800 formed on a high mobility substrate 802. The high mobility substrate 802 may include, for example, germanium, Si, SiGe, or a type III-V material. The high mobility substrate 802 may include multiple epitaxial layers composed of such materials. The silicon layer 104 is formed on the high mobility substrate 802 and a seed layer 202 is formed on the silicon layer 104 using a process as described above. A gate stack 801 that includes a dielectric material layer 302 and an electrode layer 404 is patterned over a channel region 804 of the silicon layer 104. Active regions 806 are formed adjacent to the gate stack by, for example, an ion implantation and annealing process.

FIG. 9 illustrates an exemplary embodiment of a thin film solar cell 900. The cell 900 includes an insulating glass substrate 902 having a thickness of about 2 to 4 mm. A transparent conducting oxide (TCO) layer 904 having a thickness of about 0.05 to 1 um, is deposited on the insulating glass substrate 902. The TCO layer 904 may include, for example, SnOₓ, ITO, or ZnOₓ. A thin deposited silicon junction layer 906 is deposited on the transparent conducting oxide layer 904. The junction layer 906 includes a p-type portion having a thickness of approximately 10 to 20 nm in contact with the TCO layer 904, an insulating portion having a thickness of approximately 300 to 500 nm on the p-type portion, and an n-type portion having a thickness of about 10 to 20 nm on the insulating portion. A seed layer 908 that is formed using a process described above is formed on the silicon junction layer 906, A second TCO layer 910 is formed on the seed layer 908, the layer 910 has a thickness of about 100 nm. A conductive contact layer 912 is arranged on the second TCO layer 910 the conductive contact layer 912 may be formed from, for example, a conductive metallic material, or another type of conductive material having a thickness of about 0.5 to 1 um.

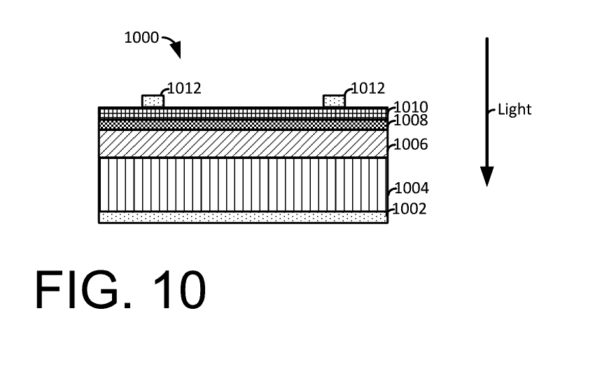

FIG. 10 illustrates an exemplary embodiment of a hetero junction solar cell device 1000. The device 1000 includes a contact layer 1002 that may include, for example, a conductive metal. A crystalline Si substrate 1004 is arranged on the contact layer 1002; the substrate 1004 has a thickness of about 300 to 500 um. The crystalline substrate 1004 can include a junction of different doping. A deposited silicon layer 1006 is arranged on the substrate 1004. The silicon layer 1006 has a thickness of about 10 nm. A seed layer 1008 that is formed using a process described above is formed on the silicon layer 1006. A TCO layer 1010 is arranged on the seed layer 1008. A grid contact 1012 may be patterned on the TCO layer 1010, and may include a conductive metal such as, for example, Al.

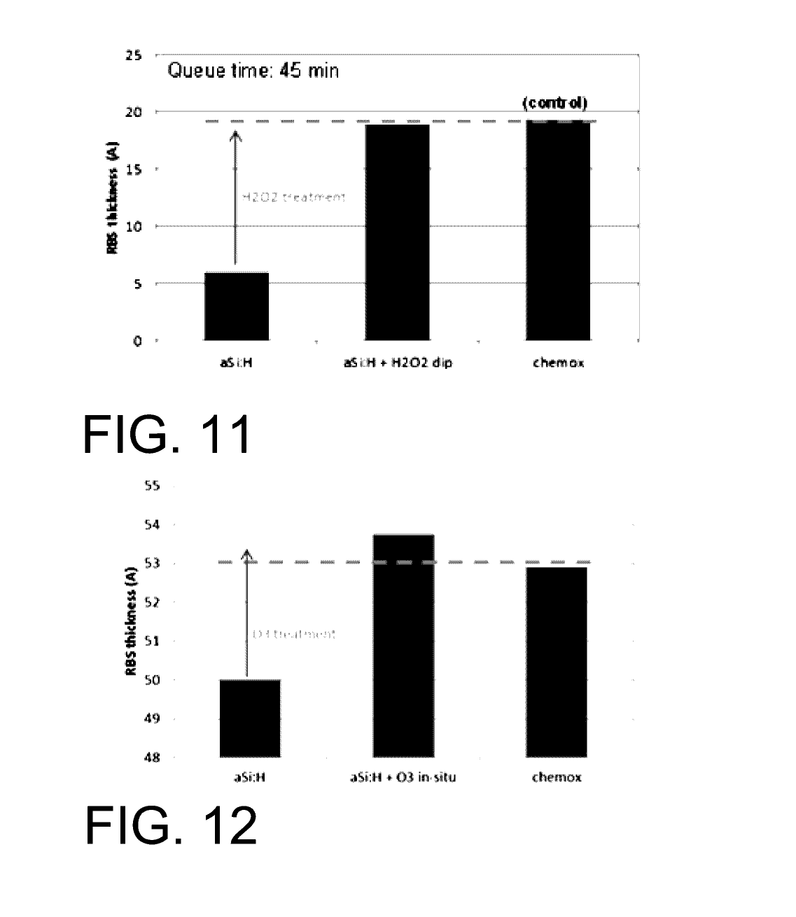

FIG. 11 illustrates a graph showing the relative thicknesses of a layer of dielectric material HfO₂ that was deposited on a layer of aSi:H without a seed layer and a layer of aSi:H that was treated to form a seed layer after a queue time of less than one hour. In this regard, the layer deposited on the untreated (no seed layer) aSi:H material has a thickness of approximately 6 angstroms, while the aSi:H that was exposed to H₂O₂ resulting in a hydrophilic seed layer has a thickness of approximately 19 angstroms, matching the control deposited on a SiOₓ hydrophilic surface.

FIG. 12 illustrates a graph showing a five day queue time and the relative thicknesses of a dielectric material (HfO₂) that was deposited on a layer of aSi:H without a seed layer and a layer of aSi:H that was treated to form a seed layer. In the illustrated graph, the thickness of the dielectric layer on the untreated aSi:H layer is approximately 50 angstroms, while the thickness of the dielectric layer on the aSi:H layer having a seed layer formed by exposure to O₃ is approximately 54 angstroms, nearly matching the control deposited on a SiOₓ hydrophilic surface.

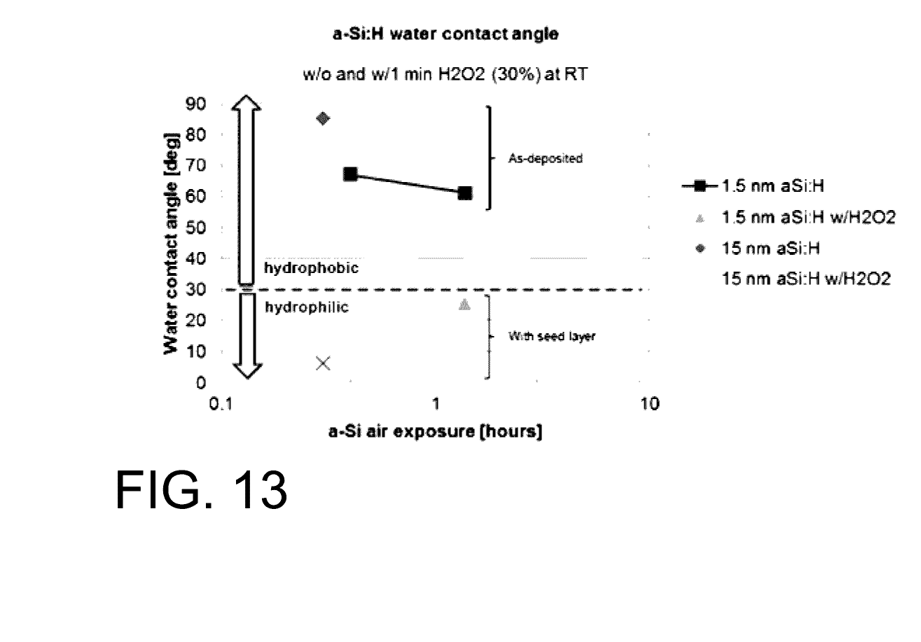

FIG. 13 illustrates a graph showing measured contact angle of H₂O₂ in degrees as a function of air exposure time in hours. Where the water contact angle of more than thirty degrees indicates a hydrophobic surface. The graph shows different deposited materials with different thicknesses such as, 1.5 nm layer of aSi:H, 1.5 nm of aSi:H w/H₂O₂, 15 nm aSi:H, and 15 nm aSi:H with H₂O₂. The surfaces treated with H₂O₂ to form a seed layer are converted to hydrophilic.

In each of the embodiments described above, a silicon layer having an H-terminated surface is formed and processed to form a seed layer having hydrophilic properties that is conducive to depositing layers of oxide materials having uniform thickness without incurring an incubation delay prior to depositing the oxide layer.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

The diagrams depicted herein are just one example. There may be many variations to this diagram or the steps (or operations) described therein without departing from the spirit of the invention. For instance, the steps may be performed in a differing order or steps may be added, deleted or modified. All of these variations are considered a part of the claimed invention.

While the preferred embodiment to the invention had been described, it will be understood that those skilled in the art, both now and in the future, may make various improvements and enhancements which fall within the scope of the claims which follow. These claims should be construed to maintain the proper protection for the invention first described.

1-14. (canceled)

15. A semiconductor device comprising:
a substrate;
a hydrophobic layer of silicon material having an H-terminated surface disposed on the substrate, wherein the hydrophobic layer of silicon material has a first water contact angle greater than 30 degrees, the hydrophobic layer of silicon being selected from the group consisting of amorphous silica, hydrogenated amorphous silica, polysilicon, nanocrystalline silicon, and hydrogenated nanocrystalline silicon, and wherein the hydrophobic layer of silicon is a separate layer independent from the substrate;
a gate stack arranged on the substrate, the gate stack comprising:
a hydrophilic seed layer having a second water contact angle of less than 30 degrees arranged on the hydrophobic layer of silicon material;
an oxide material disposed on the hydrophilic seed layer; and
a source region arranged on the substrate adjacent to the gate stack; and
a drain region arranged on the substrate adjacent to the gate stack.

16. The device of claim 15, wherein the hydrophilic seed layer includes SiO.

17-18. (canceled)

19. The device of claim 15, wherein the oxide material includes a dielectric material.

20. The device of claim 15, wherein the layer of silicon material has a thickness of approximately 1 micrometer.
